(19) United States
(12) Patent Application Publication
(10) Pub. No.: US 2024/0213372 A1
(43) Pub. Date: Jun. 27, 2024

(54) VERTICAL CHANNEL THIN FILM TRANSISTOR AND METHOD FOR MANUFACTURING THE SAME

(71) Applicant: ELECTRONICS AND TELECOMMUNICATIONS RESEARCH INSTITUTE, Daejeon (KR)

(72) Inventors: Yong Hae KIM, Daejeon (KR); Jong-Heon YANG, Daejeon (KR); Seong-Mok CHO, Daejeon (KR); Ji Hun CHOI, Daejeon (KR); Jae-Eun PI, Daejeon (KR); Chi-Sun HWANG, Daejeon (KR)

(21) Appl. No.: 18/487,625

(22) Filed: Oct. 16, 2023

(30) Foreign Application Priority Data
Dec. 21, 2022 (KR) 10-2022-0180073

(51) Int. Cl. H01L 29/786; H01L 27/06; H01L 29/417; H01L 29/66

(52) U.S. Cl. CPC H01L 29/78642; H01L 27/0629; H01L 28/20; H01L 29/41733; H01L 29/6675; H01L 29/66772; H01L 29/66969; H01L 29/78654; H01L 29/78672; H01L 29/7869; H01L 29/78696

(57) ABSTRACT

Provided is a method for manufacturing a vertical channel thin film transistor. The method for manufacturing the vertical channel thin film transistor includes forming a bottom source drain electrode, forming a first interlayer insulating layer, forming first middle source drain electrodes, forming a second interlayer insulating layer, forming a top source drain electrode, forming an opening through which portions of the bottom source drain electrode, the first middle source drain electrodes, and the top source drain electrode are exposed, forming channel layers, forming a gate insulating layer on the channel layers, the bottom source drain electrode, the first middle source drain electrodes, and the top source drain electrode, and forming gate electrodes on the gate insulating layer.

### CROSS-REFERENCE TO RELATED APPLICATIONS

This U.S. non-provisional patent application claims priority under 35 U.S.C. § 119 of Korean Patent Application No. 10-2022-0180073, filed on Dec. 21, 2022, the entire contents of which are hereby incorporated by reference.

### BACKGROUND

The present disclosure herein relates to a thin film transistor and a method for manufacturing the same, and more particularly, to an oxide semiconductor thin film transistor and a method for manufacturing the same.

In general, a vertical channel thin film transistor may be formed in a direction perpendicular to a substrate. A plurality of vertical channel thin film transistors may be separately stacked on upper and lower portions of a planarization layer in a vertical point of view. The lower vertical channel thin film transistor may be damaged by thermal stress during process of manufacturing the upper vertical channel thin film transistor.

### SUMMARY

The present disclosure provides a method for manufacturing a vertical channel thin film transistor capable of preventing or minimizing damage due to thermal stress.

An embodiment of the inventive concept provides a method for manufacturing a vertical channel thin film transistor. In an embodiment, the method for manufacturing the vertical channel thin film transistor may include: forming a bottom source drain electrode; forming a first interlayer insulating layer on the bottom source drain electrode; forming first middle source drain electrodes on the first interlayer insulating layer; forming a second interlayer insulating layer on the first middle source drain electrodes; forming a top source drain electrode on the second interlayer insulating layer; removing portions of the second interlayer insulating layer and the first interlayer insulating layer to form an opening through which portions of the bottom source drain electrode, the first middle source drain electrodes, and the top source drain electrode are exposed; forming channel layers on sidewalls of the bottom source drain electrode, the first interlayer insulating layer, the first middle source drain electrodes, the second interlayer insulating layer, and the top source drain electrode; forming a gate insulating layer on the channel layers, the bottom source drain electrode, the first middle source drain electrodes, and the top source drain electrode; and forming gate electrodes on the gate insulating layer.

In an embodiment, the method may further include removing a portion of the gate insulating layer to form a via hole through which one of the first middle source drain electrodes is exposed.

In an embodiment, the via hole may be formed on a sidewall of the opening.

In an embodiment, the gate electrodes may be connected to one of the first middle source drain electrodes by a via electrode within the opening.

In an embodiment, the forming of the gate electrodes may include forming a via electrode in the via hole.

In an embodiment, the method may further include: forming second middle source drain electrodes on the second interlayer insulating layer; and forming a third interlayer insulating layer on the second middle source drain electrodes.

In an embodiment, the opening may be formed between the second middle source drain electrodes.

In an embodiment, each of the first interlayer insulating layer and the second interlayer insulating layer may include silicon oxide formed through a plasma enhanced chemical vapor deposition method.

In an embodiment, the gate insulating layer may include silicon oxide or metal oxide formed through a rapid heat treatment method or a chemical vapor deposition method.

In an embodiment, each of the bottom source drain electrode, the first middle source drain electrodes, and the top source drain electrode may include molybdenum.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a flowchart illustrating a method for manufacturing a vertical channel thin film transistor according to an embodiment of the inventive concept;

FIG. 2, FIG. 3, FIG. 4, and FIG. 5 are process cross-sectional views illustrating the method for manufacturing the vertical channel thin film transistor according to an embodiment of the inventive concept;

FIG. 6 is a cross-sectional view illustrating an example of the vertical channel thin film transistor according to an embodiment of the inventive concept;

FIG. 7 is a cross-sectional view illustrating an example of the vertical channel thin film transistor according to an embodiment of the inventive concept;

FIG. 8 is a cross-sectional view illustrating an example of the vertical channel thin film transistor according to an embodiment of the inventive concept;

FIG. 9, FIG. 10, FIG. 11, and FIG. 12 are process cross-sectional views illustrating a method for manufacturing a vertical channel thin film transistor according to an embodiment of the inventive concept; and

FIG. 13 is a cross-sectional view illustrating an example of the vertical channel thin film transistor according to an embodiment of the inventive concept.

### DETAILED DESCRIPTION

Preferred embodiments of the present invention will be described below in detail with reference to the accompanying drawings. Advantages and features of the present invention, and implementation methods thereof will be clarified through following embodiments described with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art, and the present invention is only defined by the scope of the claims. Like reference numerals refer to like elements throughout.

In the following description, the technical terms are used only for explaining a specific exemplary embodiment while not limiting the present invention. In this specification, the terms of a singular form may comprise plural forms unless specifically mentioned. The meaning of ‘comprises’ and/or ‘comprising’ specifies a component, an operation and/or an element does not exclude other components, operations and/or elements. Since preferred embodiments are provided below, the order of the reference numerals given in the description is not limited thereto.

Additionally, the embodiment in the detailed description will be described with sectional views as ideal exemplary views of the present invention. In the figures, the dimensions of layers and regions are exaggerated for clarity of illustration. Accordingly, shapes of the exemplary views may be modified according to manufacturing techniques and/or allowable errors. Therefore, the embodiments of the present invention are not limited to the specific shape illustrated in the exemplary views, but may include other shapes that may be created according to manufacturing processes.

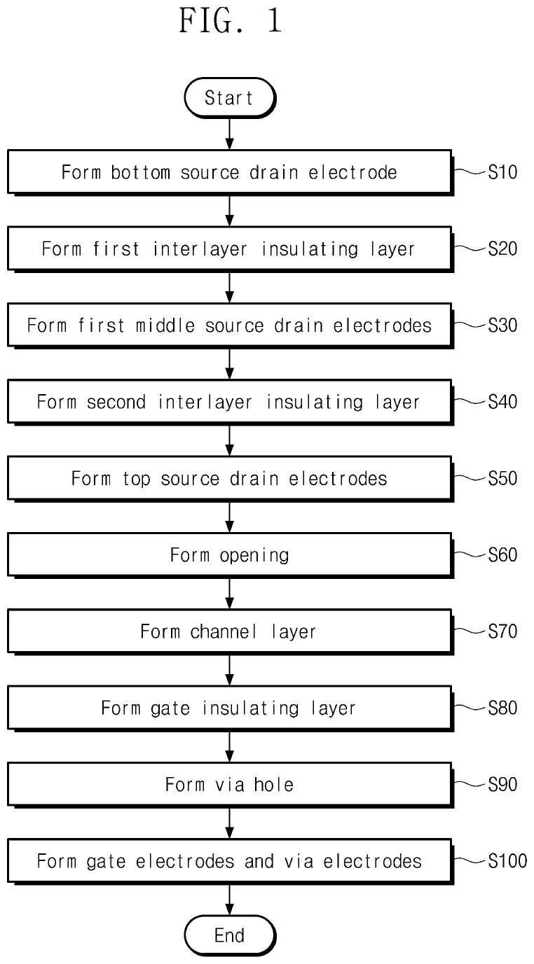

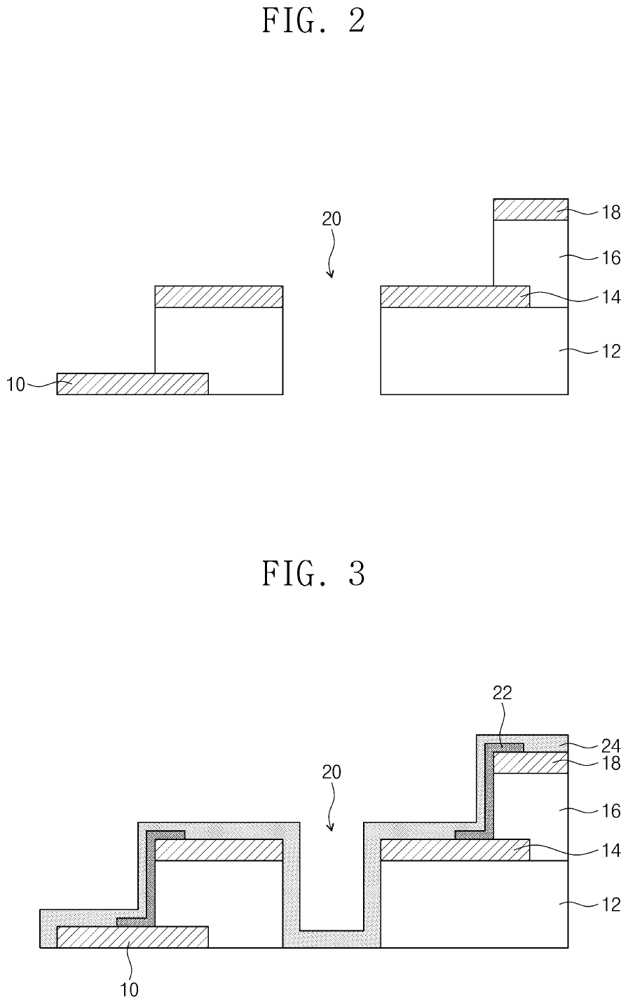

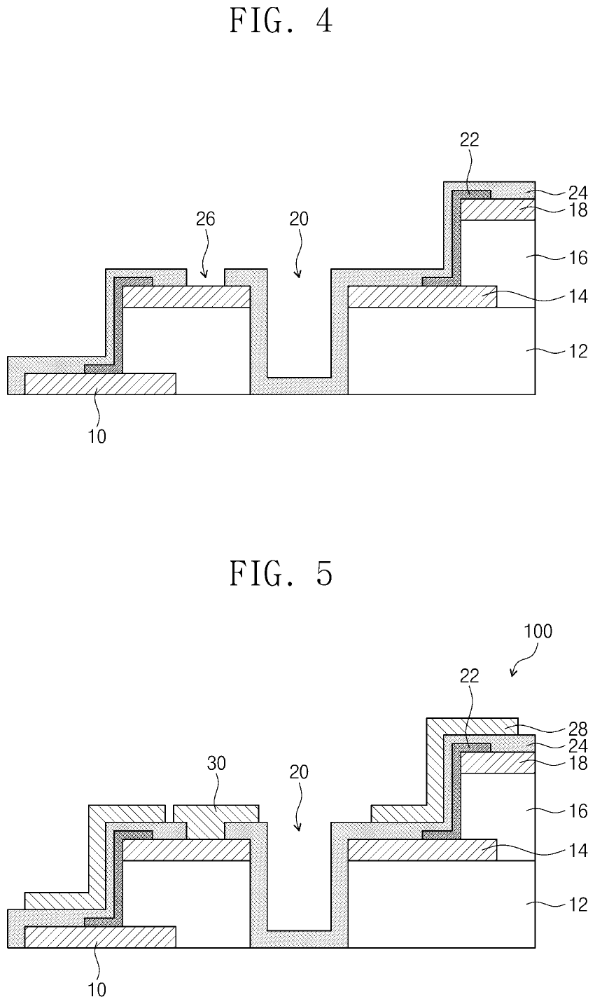

FIG. 1 is a flowchart illustrating a method for manufacturing a vertical channel thin film transistor according to an embodiment of the inventive concept. FIGS. 2 to 5 are process cross-sectional views illustrating the method for manufacturing the vertical channel thin film transistor according to an embodiment of the inventive concept.

Referring to FIGS. 1 and 2, a bottom source drain electrode 10 is formed (S10). Although not shown, the bottom source drain electrode 10 may be formed on one side of a substrate. The substrate may include a silicon wafer. The bottom source drain electrode 10 may be formed through a metal deposition process, a photolithography process, and an etching process. For example, the bottom source drain electrode 10 may include molybdenum (Mo). Alternatively, the bottom source drain electrode 10 may include a metal of gold (Au), silver (Ag), copper (Cu), aluminum (Al), tungsten (W), cobalt (Co), or manganese (Mg), but the embodiment of the inventive concept is not limited thereto.

Next, a first interlayer insulating layer 12 is formed on the bottom source drain electrode 10 (S20). The first interlayer insulating layer 12 may be formed to be flat on the substrate. The first interlayer insulating layer 12 may include silicon oxide formed through a plasma enhanced chemical vapor deposition method.

Then, first middle source drain electrodes 14 are formed on the first interlayer insulating layer 12 (S30). The first middle source drain electrodes 14 may be formed through a metal deposition process, a photolithography process, and an etching process. For example, each of the first middle source drain electrodes 14 may include molybdenum (Mo). Alternatively, each of the first middle source drain electrodes 14 may be made of gold (Au), silver (Ag), copper (Cu), aluminum (Al), tungsten (W), cobalt (Co), or manganese (Mg), but the embodiment of the inventive concept is not limited thereto.

Referring to FIGS. 1 and 2 continuously, a second interlayer insulating layer 16 is formed on the first middle source drain electrodes 14 (S40). The second interlayer insulating layer 16 may be flat. The second interlayer insulating layer 16 may include silicon oxide formed through a plasma enhanced chemical vapor deposition method.

Next, a top source drain electrode 18 is formed on the second interlayer insulating layer 16 (S50). The top source drain electrode 18 may be formed through a metal deposition process, a photolithography process, and an etching process. For example, the top source drain electrode 18 may include molybdenum (Mo). Alternatively, the top source drain electrode 18 may include a metal of gold (Au), silver (Ag), copper (Cu), aluminum (Al), tungsten (W), cobalt (Co), or manganese (Mg), but the embodiment of the inventive concept is not limited thereto.

Although not shown, a protective layer may be formed on the top source drain electrode 18. The protective layer may include silicon oxide or silicon nitride formed through a chemical vapor deposition method, but the embodiment of the inventive concept is not limited thereto.

Referring to FIGS. 1 and 3, an opening 20 is formed by removing a portion of each of the protective layer, the second interlayer insulating layer 16, and the first interlayer insulating layer 12 (S60). The opening 20 may expose portions of sidewalls and top surfaces of the bottom source drain electrode 10, the first middle source drain electrodes 14, and the top source drain electrode 180. The opening 20 may be formed between the first middle source drain electrodes 14.

Next, a channel layer 22 is formed on sidewalls of the first interlayer insulating layer 12, the first middle source drain electrodes 14, the second interlayer insulating layer 16, and the top source drain electrode 18 (S70). The channel layer 22 may include crystalline silicon, polysilicon, or a metal oxide semiconductor formed through an atomic layer deposition method or a chemical vapor deposition method. The channel layer 22 may be connected between the bottom source drain electrode 10 and the first middle source drain electrodes 14 and between the first middle source drain electrode 14 and the top source drain electrode 18. The channel layer 22 may have a stair shape.

In a method for manufacturing the vertical channel thin film transistor (see reference numeral 100 in FIG. 7) according to an embodiment of the inventive concept, the channel layer 22 having the stair shape may be formed in a single process to prevent or minimize thermal stress occurring on the bottom source drain electrode 10, the first middle source drain electrodes 14, and the top source drain electrode 18.

Then, a gate insulating layer 24 is formed on the channel layer 22, the bottom source drain electrode 10, the first interlayer insulating layer 12, the first middle source drain electrodes 14, the second interlayer insulating layer 16, and the top source drain electrode 18 (S80). The gate insulating layer 24 may include silicon oxide or metal oxide formed through a rapid heat treatment method or a chemical vapor deposition method.

Referring to FIGS. 1 and 4, a via hole 26 is formed by removing a portion of each of the gate insulating layer 24 and the second interlayer insulating layer 16 (S90). The via hole 26 may expose portions of the first middle source drain electrodes 14. The via hole 26 may be formed through a photolithography process and an etching process.

Referring to FIGS. 1 and 5, gate electrodes 28 and via electrodes 30 are formed on the channel layer 22 and in the via hole 26, respectively (S100). Thus, the method for manufacturing the vertical channel thin film transistor 100 may be completed. The gate electrodes 28 and the via electrode 30 may include a metal such as gold (Au), silver (Ag), copper (Cu), aluminum (Al), tungsten (W), molybdenum (Mo), cobalt (Co), or manganese (Mg), which is formed through a physical vapor deposition method or a chemical vapor deposition method, but the embodiment of the inventive concept is not limited thereto. The gate electrodes 28 and the via electrode 30 may be formed through a metal deposition process, a photolithography process, and an etching process. The gate electrodes 28 and the via electrode 30 may be separated from each other.

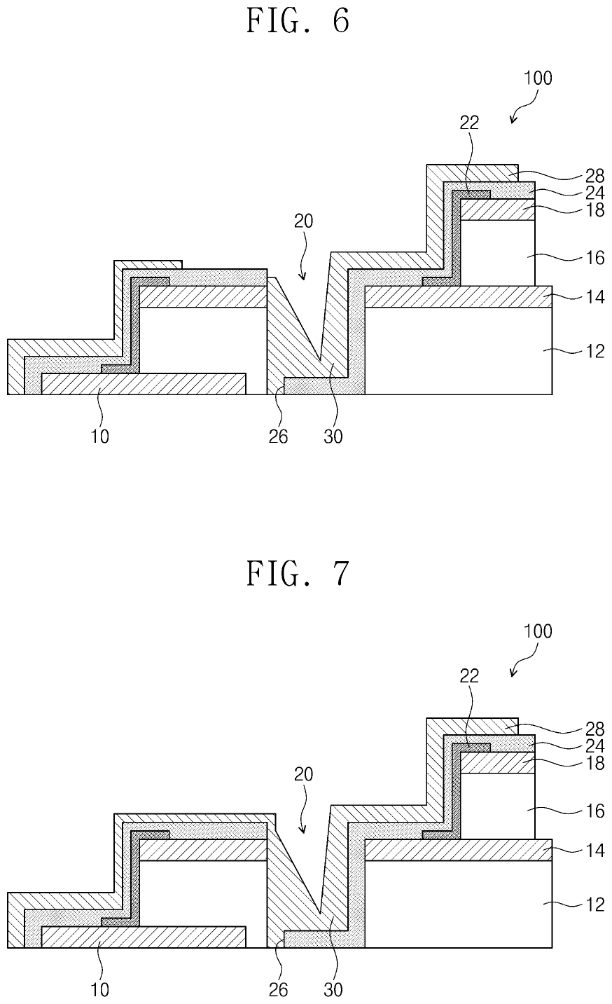

FIG. 6 is a cross-sectional view illustrating an example of the vertical channel thin film transistor 100 according to an embodiment of the inventive concept.

Referring to FIG. 6, the via electrode 30 of the vertical channel thin film transistors 100 according to an embodiment of the inventive concept may connect the one-side gate electrode 28 to the other-side first middle source drain electrode 14. The via electrode 30 may be defined in the opening 20 and the via hole 26. The via electrode 30 may be defined in a bottom surface and sidewalls of the opening 20. The via hole 26 may be defined in the opening 20.

FIG. 7 is a cross-sectional view illustrating an example of the vertical channel thin film transistor 100 according to an embodiment of the inventive concept.

Referring to FIG. 7, in the via electrode 30 of the vertical channel thin film transistors 100 according to an embodiment of the inventive concept may connect the one-side gate electrode 28 to the other-side gate electrode 28 and the first middle source drain electrode 14. The via electrode 30 may allow one of the vertical channel thin film transistors 100 to be provided as a resistor. That is, the via electrode 30 may connect the vertical channel thin film transistor 100 to each other through the resistor.

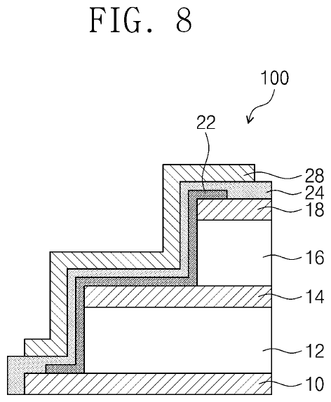

FIG. 8 is a cross-sectional view illustrating an example of the vertical channel thin film transistor 100 according to an embodiment of the inventive concept.

Referring to FIG. 8, the vertical channel thin film transistors 100 according to an embodiment of the inventive concept may have a stair shape in a vertical point of view. One of the vertical channel thin film transistors 100 may be provided on one side of the bottom source drain electrode 10, and the other one of the vertical channel thin film transistors 100 may be provided on the other side of each of the bottom source drain electrode 10 and the first middle source drain 14.

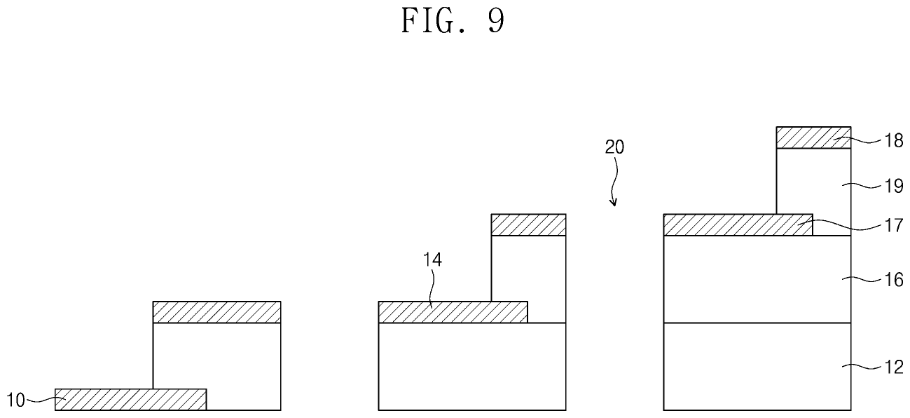

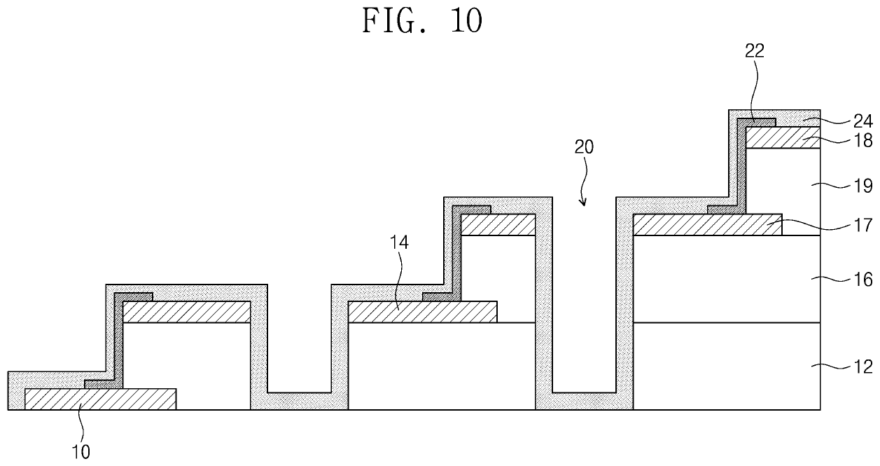

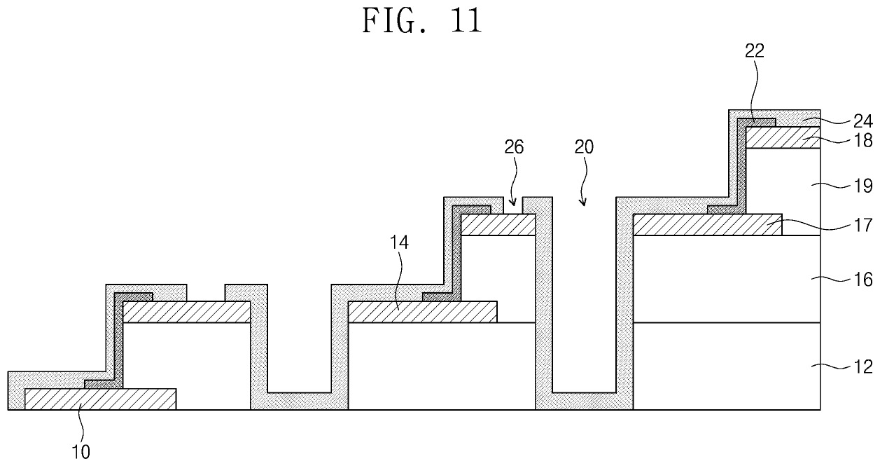

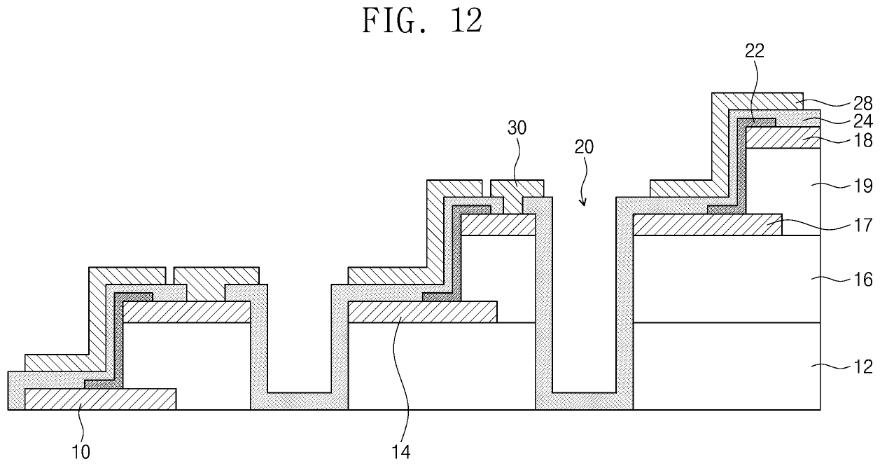

FIGS. 9 to 12 are process cross-sectional views illustrating a method for manufacturing the vertical channel thin film transistor according to an embodiment of the inventive concept.

Referring to FIG. 9, a method for manufacturing the vertical channel thin film transistor 100 according to an embodiment of the inventive concept further includes a process of forming second middle source drain electrodes 17 and a process of forming a third interlayer insulating layer 19.

The second middle source drain electrodes 17 may be formed between the second interlayer insulating layer 16 and the top source drain electrode 18. Some of the second middle source drain electrodes 17 may overlap the first middle source drain electrodes 14. Each of the second middle source drain electrodes 17 may include molybdenum (Mo).

The third interlayer insulating layer 19 may be formed between the second middle source drain electrode 17 and the top source drain electrode 18. The third interlayer insulating layer 19 may include silicon oxide formed through a plasma enhanced chemical vapor deposition method.

The process (S10) of forming the bottom source drain electrode 10 to the process (S40) of forming the second interlayer insulating layer 16, the process (S50) of forming the top source drain electrode 18, and the process (S60) of forming openings 20 may be the same as those in FIGS. 1 and 2. At least one of the openings 20 may be provided between the second middle source drain electrodes 17.

Referring to FIGS. 1 and 10, a channel layer 22 is formed on the sidewalls of the bottom source drain electrode 10, the first interlayer insulating layer 12, the first middle source drain electrode 14, the second interlayer insulating layer 16, the second middle source drain electrode 17, the third interlayer insulating layer 19, and the top source drain electrode 18 (S70).

Then, the gate insulating layer 24 is formed on the channel layer 22, the bottom source drain electrode 10, the first interlayer insulating layer 14, the first middle source drain electrode 14, the second interlayer insulating layer 16, the second middle source drain electrode 17, the third interlayer insulating layer 19, and the top source drain electrode 18 (S80).

Referring to FIGS. 1 and 11, a portion of the gate insulating layer 24 may be removed to form a via hole 26 through which the first middle source drain electrodes 14 are exposed (S90).

Referring to FIGS. 1 and 12, gate electrodes 28 and via electrodes 30 are formed in the openings 20 and the via hole 26, respectively (S100).

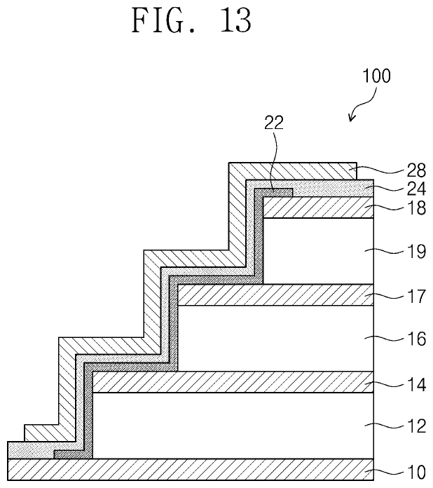

FIG. 13 is a cross-sectional view illustrating an example of the vertical channel thin film transistor 100 according to an embodiment of the inventive concept.

Referring to FIG. 13, the bottom source drain electrode 10, the first interlayer insulating layer 12, the first middle source drain electrode 14, the second interlayer insulating layer 16, the second middle source drain electrode 17, the third interlayer insulating layer 19, and the top source drain electrode 18 of the vertical channel thin film transistor 100 according to an embodiment of the inventive concept may be arranged in the stair shape. The sidewalls of the first middle source drain electrode 14, the second middle source drain electrode 17, and the top source drain electrode 18 may be aligned with the sidewalls of the first interlayer insulating layer 12, the second interlayer insulating layer 16, and the third interlayer insulating layer 12, respectively. That is, the vertical channel thin film transistors 100 may be arranged in the stair shape.

As described above, in the method for manufacturing the vertical channel thin film transistor according to the embodiment of the inventive concept, the channel layer having the stair shape may be formed through the single process on the bottom source drain electrode, the first middle source drain electrodes, and the top source drain electrode to prevent or minimize the thermal stress.

Although the embodiment of the present invention is described with reference to the accompanying drawings, those with ordinary skill in the technical field of the present invention pertains will be understood that the present invention can be carried out in other specific forms without changing the technical idea or essential features. Thus, the above-disclosed embodiments are to be considered illustrative and not restrictive.

What is claimed is:

1. A method for manufacturing a vertical channel thin film transistor, the method comprising:
forming a bottom source drain electrode;
forming a first interlayer insulating layer on the bottom source drain electrode;
forming first middle source drain electrodes on the first interlayer insulating layer;
forming a second interlayer insulating layer on the first middle source drain electrodes;
forming a top source drain electrode on the second interlayer insulating layer;
removing portions of the second interlayer insulating layer and the first interlayer insulating layer to form an opening through which portions of the bottom source drain electrode, the first middle source drain electrodes, and the top source drain electrode are exposed;
forming channel layers on sidewalls of the bottom source drain electrode, the first interlayer insulating layer, the first middle source drain electrodes, the second interlayer insulating layer, and the top source drain electrode;
forming a gate insulating layer on the channel layers, the bottom source drain electrode, the first middle source drain electrodes, and the top source drain electrode; and
forming gate electrodes on the gate insulating layer.

2. The method of claim 1, further comprising removing a portion of the gate insulating layer to form a via hole through which one of the first middle source drain electrodes is exposed.

3. The method of claim 2, wherein the via hole is formed on a sidewall of the opening.

4. The method of claim 3, wherein the gate electrodes are connected to one of the first middle source drain electrodes by a via electrode within the opening.

5. The method of claim 2, wherein the forming the gate electrodes comprises forming a via electrode in the via hole.

6. The method of claim 1, further comprising:
forming second middle source drain electrodes on the second interlayer insulating layer; and
forming a third interlayer insulating layer on the second middle source drain electrodes.

7. The method of claim 1, wherein the opening is formed between the second middle source drain electrodes.

8. The method of claim 1, wherein each of the first interlayer insulating layer and the second interlayer insulating layer comprises silicon oxide formed through a plasma enhanced chemical vapor deposition method.

9. The method of claim 1, wherein the gate insulating layer comprises silicon oxide or metal oxide formed through a rapid heat treatment method or a chemical vapor deposition method.

10. The method of claim 1, wherein each of the bottom source drain electrode, the first middle source drain electrodes, and the top source drain electrode comprises molybdenum.
